(19) United States
(12) Patent Application Publication
(10) Pub. No.: US 2019/0204674 A1
(43) Pub. Date: Jul. 4, 2019

(54) LIQUID CRYSTAL PANEL AND MANUFACTURING METHOD THEREOF AND DISPLAY DEVICE

(71) Applicant: Huizhou China Star Optoelectronics Technology Co., Ltd., Huizhou Guangdon (CN)

(72) Inventor: Xiaohong JING, Huizhou Guangdong (CN)

(21) Appl. No.: 15/749,366

(22) PCT Filed: Jan. 24, 2018
(86) PCT No.: PCT/CN2018/073984

§ 371 Date: Jan. 31, 2018

(30) Foreign Application Priority Data
Dec. 28, 2017 (CN) 201711464706.3

(51) Int. Cl. G02F 1/1335; G02F 1/1345; G02F 1/1341; H05K 1/18; C09J 9/02; H05K 3/32

(52) U.S. Cl. CPC G02F 1/133528; G02F 1/133514; G02F 1/13452; H05K 3/321; H05K 1/189; C09J 9/02; G02F 1/1341

(57) ABSTRACT

The present disclosure discloses a liquid crystal panel, including a TFT substrate, a CF substrate, liquid crystal, and a first polarizer, wherein further includes a non-displayed binding end for connecting a COF, the first polarizer completely covers the TFT substrate, an encapsulant is disposed between the first polarizer and the binding end. The present disclosure further discloses a manufacturing method of the liquid crystal panel and a display device. In the liquid crystal panel and the manufacturing method thereof, by attaching a thermoplastic film on the binding end and the non-binding end and pressing the polarizer, the shadowing of the binding end can be realized in one step arid the side is encapsulated to simplify the process. And because of the process, just attached plastic mold, attached to the process of precision is not high, and without dispensing, greatly reducing production costs.

### RELATED APPLICATIONS

The present application is a National Phase of International Application Number PCT/CN2018/073984, filed Jan. 24, 2018, and claims the priority of China Application 201711464706.3, filed Dec. 28, 2017.

### FIELD OF THE DISCLOSURE

The present disclosure relates to a liquid crystal display technology field, and more particularly to a liquid crystal panel and a manufacturing method thereof and a display device.

### BACKGROUND OF THE DISCLOSURE

Bezel Less LCD gradually become a popular design trend, borderless display refers to the screen frame extremely narrow display device, the screen will be combined with the display screen and the border resulting in the visual design can not see the physical border. One of its major advantages is the outstanding appearance, compared with the past with a thick border of the display, no border can bring a real sense of the horizontal screen, so that the appearance of a more stylish. Another big advantage is that the display without borders technology can achieve good display splicing, to achieve two-screen, triple screen or even multi-screen, and no border monitor can maximize the effect of the display screen. In addition, the borderless display gives the user a wider viewing angle and eliminates the bondage of the original thick border display.

The liquid crystal display mainly includes two parts of a liquid crystal panel and a backlight module. At present, the frameless design of the liquid crystal display is usually realized by eliminating the front frame of the module and the front shell of the whole machine. The liquid crystal display mainly includes two parts of a liquid crystal panel and a backlight module. At present, the bezel less design of the liquid crystal display is usually realized by eliminating the front frame of the module and the front shell of the whole display. The liquid crystal panel usually includes a color filter (CF) substrate and an array (Thin Film Transistor array, TFT Array) substrate. The two substrates are filled with liquid crystal after being aligned with each other. In the prior art, the frameless method for realizing the liquid crystal panel is generally implemented by the following process: S1: facing outward the color filter substrate, and the array substrate facing the backlight, wherein one side edge of the array substrate extends out of a corresponding side of the color filter substrate to form a binding area for connection; S2, respectively attaching the polarizer on the upper surface and the lower surface of the color filter substrate and the array substrate, at this time, the sizes of the polarizer and the color filter substrate on the color filter substrate are the same; S3, connecting COF (Chip On Film) in the binding area to further connect the mother board in the backlight module; S4, dispensing the binding area after connection; S5, side packaging the side of the liquid crystal panel after the dispensing is completed; the step S4 involves the dispensing, if the process of manual dispensing, the manual operation of dispensing more casual, less consistent, it is difficult to achieve standardized manufacturing. Dispensing effect of poor volatility, can not meet the precision requirements of the dispensing process, resulting in low yield and low production efficiency of the LCD panel. If using dispensing equipment dispensing, as the dispensing equipment for the process is expensive, resulting in a high production cost of the liquid crystal panel. In the prior art, it needs to be filled before being encapsulated, and the process is complicated. All of the above defects result in that the bezel less display can not be widely popularized and popularized.

### SUMMARY OF THE DISCLOSURE

In view of the defects in the prior art, the present disclosure provides a liquid crystal panel and a method of manufacturing the same, and a display device, so as to provide a bezel less liquid crystal panel with a low cost and a simple manufacturing process.

In order to achieve the above object, the present disclosure adopts the following technical solutions.

The present disclosure provides a liquid crystal panel, including a TFT substrate, a CF substrate disposed on the TFT substrate, liquid crystal filled between the TFT substrate and the CF substrate, and a first polarizer attached to an outer surface of the CF substrate, wherein at least one end surface of the TFT substrate is beyond the side end surface of the CF substrate to form a non-displayed binding end for connecting a COF, the first polarizer completely covers the TFT substrate, an encapsulant is disposed between the first polarizer and the binding end.

Wherein remaining ends of the TFT substrate are beyond an end surface on a corresponding side of the CF substrate to form a non-displayed non-binding end, the non-binding end is connected to the binding end and surrounds the CF substrate, the encapsulant is disposed between the first polarizer and the non-binding end.

Wherein the binding end and/or the non-binding end is provided with a concave groove downwardly, and the encapsulant is arranged in the concave groove and extends out of an upper end surface of the concave groove.

Wherein the encapsulant is formed by melting a thermoplastic film.

Wherein the binding end is laminated with an anisotropic conductive adhesive film, and the COF is electrically connected with a conductive terminal of the binding end through the anisotropic conductive adhesive film.

Another object of the present disclosure is to provide a method for manufacturing a liquid crystal panel, including:
cutting a mother board to form a liquid crystal cell with an externally disposed CF substrate;
wherein the TFT substrate of the liquid crystal cell includes a binding end;
electrically connecting a COF with the binding end;
attaching a thermoplastic film to the binding end;
placing a first polarizer on an upper end of the CF substrate and contacting the first polarizer with the thermoplastic film;
vacuum pressing the first polarizer so that the first polarizer is attached to an outer surface of the CF substrate while the thermoplastic film is heated and melted to fill a cavity between the first polarizer and the binding end; and
curing the filled thermoplastic film by UV light.

Wherein the TFT substrate of the liquid crystal cell further includes a non-binding end; in attaching the thermoplastic film, the thermoplastic film must be attached to a surface of the non-binding end at the same time; the thermoplastic film is heated and melted to fill the cavity between the first polarizer and the non-binding end.

Wherein a surface of thermoplastic film protrudes from an upper surface of the CF substrate before vacuum pressing.

Wherein a position of the vacuum pressing is on the first polarizer opposite to the thermoplastic film.

Another object of the present disclosure is to provide a display device, including a backlight module and a liquid crystal panel, the backlight module is disposed on a side of the TFT substrate facing away from the CF substrate and light emitted from the backlight module is emitted from a surface of the CF substrate after passing through the TFT.

Compared with the prior art, the liquid crystal panel provided by the disclosure uses the polarizer on the CF substrate as the viewing surface and the binding end of the liquid crystal panel between the polarizer and the TFT substrate, the encapsulant formed by melting the thermoplastic film fills the gap between the polarizer and the TFT substrate without the need to set a binding frame to obscure the bind end, thus realizing the bezel less design and enhancing the visual effect and viewing experience of the whole machine. At the same time, the grooves in the liquid crystal panel are designed so that the width of the non-display area is reduced in the liquid crystal panel with the same width, but the tightening of the polarizer with the TFT substrate is rather reversed. In the manufacturing method of the liquid crystal panel provided by the present disclosure, by attaching a thermoplastic film on the binding end and the non-binding end and pressing the polarizer, the shadowing of the binding end can be realized in one step and the side is encapsulated to simplify the process. And because of the process, just attached plastic mold, attached to the process of precision is not high, and without dispensing, greatly reducing production costs.

### BRIEF DESCRIPTION OF THE DRAWINGS

FIG. 1(a) is a front view of a schematic diagram before a CF substrate attached with a polarizer in a liquid crystal panel of the present disclosure.

FIG. 1(b) is a side view of a schematic diagram before a CF substrate attached with a polarizer in a liquid crystal panel of the present disclosure.

FIG. 1(c) is a top view of a schematic diagram before a CF substrate attached with a polarizer in a liquid crystal panel of the present disclosure.

FIG. 2(a) is a front view of a schematic diagram after a CF substrate attached with a polarizer in a liquid crystal panel of the present disclosure.

FIG. 2(b) is a side view of a schematic diagram after a CF substrate attached with a polarizer in a liquid crystal panel of the present disclosure.

FIG. 2(c) is a top view of a schematic diagram after a CF substrate attached with a polarizer in a liquid crystal panel of the present disclosure.

FIG. 3 is a front view of a schematic diagram of the display device of the present disclosure.

FIG. 4 is a schematic flow chart of a method for manufacturing a liquid crystal panel of the present disclosure.

### DETAILED DESCRIPTION OF PREFERRED EMBODIMENTS

In order to make the objectives, technical solutions and advantages of the present disclosure more comprehensible, the present disclosure is further described in detail below with reference to the accompanying drawings and embodiments. It should be understood that the specific embodiments described herein are merely used to explain the present disclosure, and are not intended to limit the present disclosure.

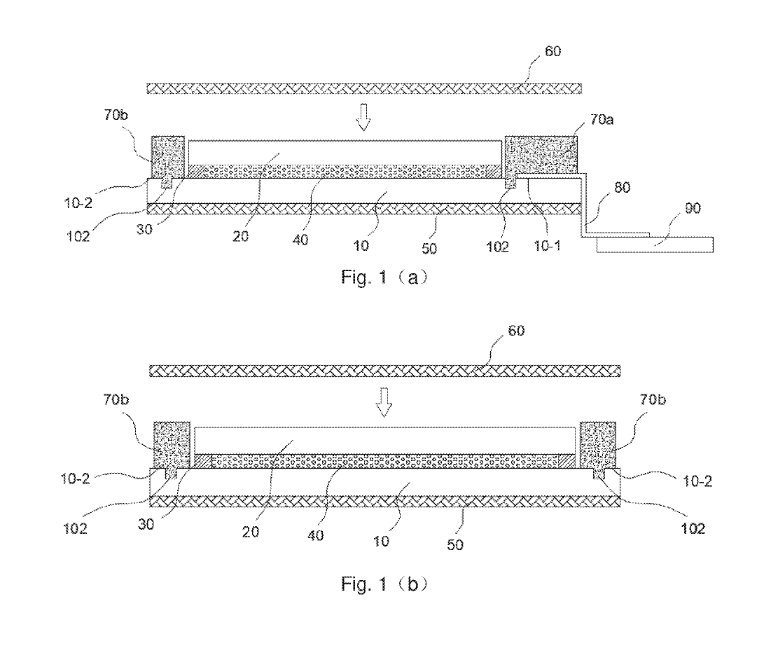

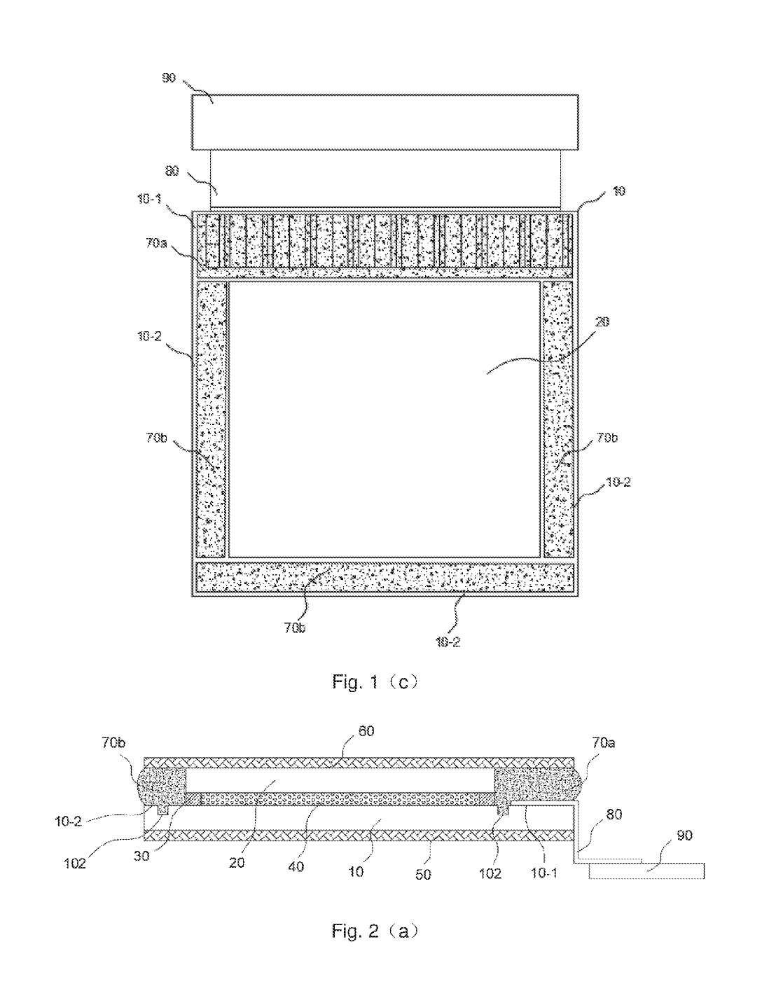

Referring to FIG. 2(a) and FIG. 2(b), a liquid crystal panel provided in an embodiment of the present disclosure includes a TFT (Thin Film Transistor) substrate 10 opposite to a liquid crystal display and a CF (Color filter) substrate 20 disposed on the TFT substrate 10 and liquid crystal 40 disposed between the TFT substrate 10 and the CF substrate 20. The liquid crystal 40 can be encapsulated by the encapsulant 30 between the TFT substrate 10 and the CF substrate 20. The second polarizer 50 and the first polarizer 60 are respectively attached to the outer surface of the TFT substrate 10 and the CF substrate.

Wherein, referring to FIG. 2(a) and FIG. 2(b), each side of the CF substrate 20 covered on the encapsulant 30 is flush with each side of the encapsulant 30, it can be understood that the area provided with the liquid crystal 40 forms the display area of the liquid crystal panel; for the arrangement of the liquid crystal panel binding ends, at least one end surface of the TFT substrate 10 is beyond the end surface on the side of the CF substrate 20, of course, this is also exceeded with respect to the encapsulant 30, and the excess portion forms a non-displayed binding end 10-1 for connecting the COFs. In the present design, the first polarizer 60 provided on the CF substrate 20 is used as the viewing surface. Therefore, the shape and size of the first polarizer 60 are always the same as that of the TFT substrate 10, so that the first polarizer 60 completely covers the TFT substrate 10. It can be understood that, at this time, the first polarizer 60 is beyond the CF substrate 20, an open cavity is formed between the side of the first polarizer 60, the side of the encapsulant 30 and the side of the CF substrate 20 and the binding end 10-1, wherein the cavity is filled with the encapsulant for packaging; in order to further fix the first polarizer 60 on the CF substrate 20, all four sides of the TFT substrate 10 are beyond the encapsulant 30, that is, a non-display area is formed on the periphery of the CF substrate 20, one or both sides of the excess part can be designed to be wider than the width of the binding end so as to facilitate the design of the alignment. The remaining excess width as the connection portion can be set smaller, that is, both to meet the connection as much as possible to reduce the non-display area to expand the display area. As an embodiment of the present disclosure, in conjunction with FIGS. 1(a), 1(b), 2(a) and 2(b). In this embodiment, the one end surface of the TCF substrate 10 extends beyond the wider end surface of the CF substrate 20 to form a non-displayed binding end 10-1 for connecting to the COF80, the binding end 10-1 is provided with a conductive terminal so that the COF80 is electrically connected with the conductive terminal. The other three sides are beyond the narrower width to form a non-displayed non-binding end 10-2, so that a cavity is formed between the upper first polarizer 60 and the lower non-binding end 10-2, the cavity is fixed by filling the encapsulant with the first polarizer 60 on the CF substrate 20 and the TFT substrate 10.

Specifically, as shown in FIGS. 1(c) and 2(c), binding end 10-1 since the conductive terminals need to be disposed, large of metal traces, such as Fanout, WOA (Wire On Array) and Gate On Array (GOA) are designed thereon. The metal pattern density of these traces is relatively large, which causes obvious reflections and affects the visual effect of the whole machine. Therefore, in order to shield the reflective trace, the metal traces need to be covered after the alignment is completed. On the basis of the above embodiment, when the end surfaces of the four sides of the TFT substrate 10 are all exceeded, the first polarizer 60 at the upper end forms a one-dimensional cavity between the TFT substrates 10, the cavity is filled with an encapsulant to encapsulate. The encapsulant includes a first encapsulant 70a filled in the binding end 10-1 and a second encapsulant 70b filled in the non-bound end 10-2. The first encapsulant 70a not only tightly connects the upper first polarizer 60 with the lower TFT substrate 10, but also shields the alignment of the binding end 10-1. Wherein, the encapsulant is formed by melting the thermoplastic film, which avoids dispensing by the prior art, does not require dispensing equipment, saves production costs, at the same time the accuracy of the method is not demanding, filling more urgent and not easy to produce bubbles, improve product yield.

Wherein, in conjunction with FIGS. 2(a) and 2(b), in order to make the connection between the first polarizer 60 at the upper end and the TFT substrate 10 at the lower end more tightened, a concave groove 102 recessed downward may be provided on the binding end 10-1 and/or the non-binding end 10-2. Herein, the downward finger is recessed downward from the upper surface of the TFT substrate 10, it can be understood that the recessed groove 102 is communicated with the cavity between the first polarizer 60 and the TFT substrate 10, the encapsulant can be directly disposed in the groove 102 and also disposed on the upper surface of the groove 102, after the thermoplastic film melts into the groove 102, the design can increase the fastening between the first polarizer 60 and the TFT substrate 10 at the lower end without reducing the width of the non-display area. Wherein, a groove 102 is provided on both the binding end 10-1 and the non-binding end 10-2, and the groove 102 formed is communicated with and around the CF substrate 20 to form an annular groove, the method is convenient for attaching the thermoplastic film directly to the thermoplastic film, and the annular thermoplastic film sleeve is directly attached to the annular groove so as to be conveniently attached, thereby reducing the precision requirement in the attaching process. In order to reduce the width of the non-display area as much as possible without affecting the tightness between the first polarizer 60 and the TFT substrate 10, the annular groove may be provided with a plurality of turns, a plurality of annular grooves are arranged in the thermoplastic film, the thermoplastic film is melted and cured to form an encapsulant, so that the non-display area is reduced, the fastening between the first polarizer 60 and the TFT substrate 10 is increased, the user's visual range is expanded, the user experience is improved, and the filling and packaging process is also simplified.

Wherein, in combination with FIG. 2(a) and FIG. 2(c), the binding end 10-1 is press-fitted with an anisotropic conductive adhesive film, one end of the COF80 is electrically connected to the conductive terminal of the binding end 10-1 through the anisotropic conductive adhesive film, and the other end is electrically connected with a PCB (Printed Circuit Board) 90.

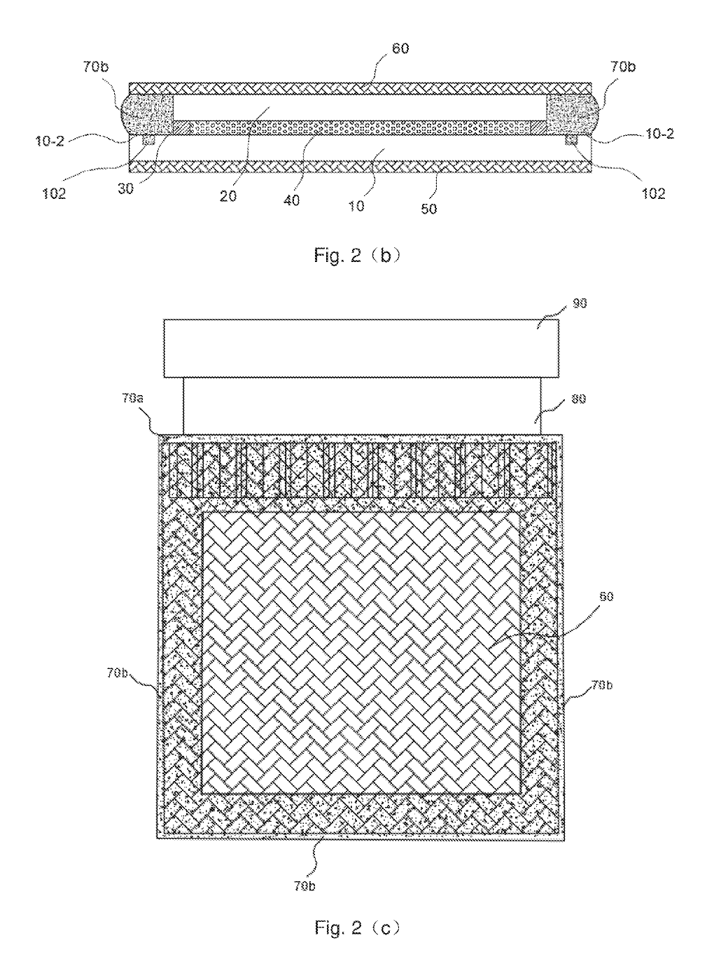

Referring to FIG. 3, correspondingly, the display device in the present embodiment includes a backlight module 100 and the liquid crystal panel described above. The backlight module 100 is disposed on a side of the TFT substrate 10 facing away from the CF substrate 20, the light emitted from the backlight module 100 is emitted from the surface of the CF substrate 20 after passing through the TFT substrate 10. The COF80 includes a flexible circuit board and a driver IC (integrated circuit) on the flexible circuit board. The LCD panel is connected to the PCB 90 through a COF80 flexible circuit board.

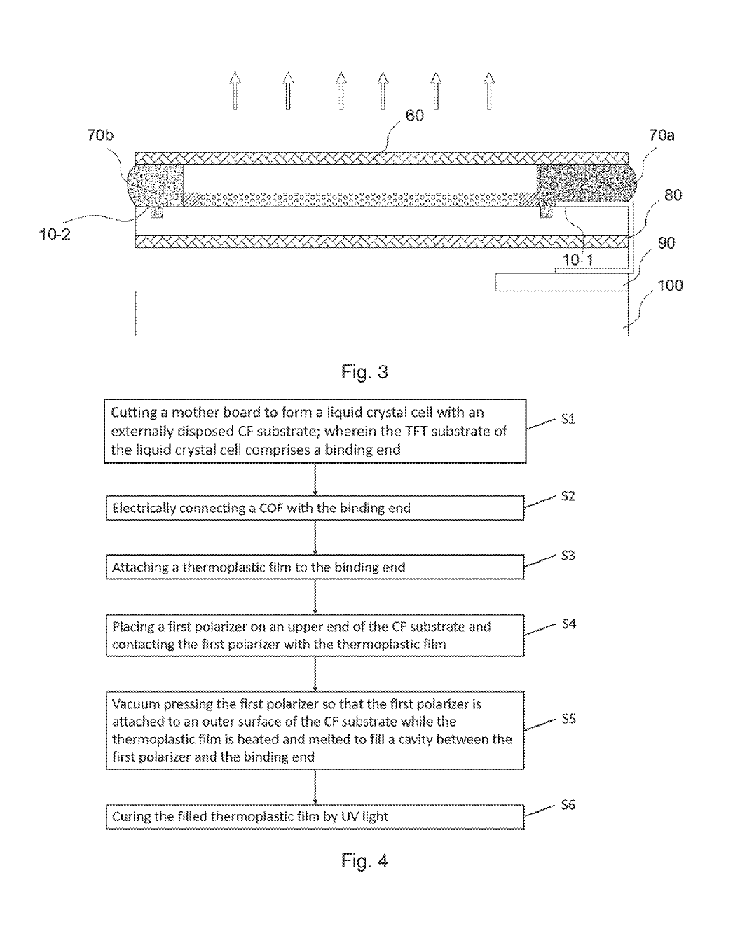

Based on the above structure of the liquid crystal panel, the manufacturing method of the present embodiment has been improved. In combination with FIGS. 1(a), 1(b), 1(c), 2(a), 2(b), 2(c) and FIG. 4, the manufacturing method of the liquid crystal panel of the present embodiment includes the steps of:
S1, cutting a mother board to form a liquid crystal cell with an externally disposed CF substrate; wherein the TFT substrate 10 of the liquid crystal cell includes a binding end 10-1;
S2, electrically connecting a COF80 with the binding end 10-1;
S3, attaching a thermoplastic film to the binding end 10-1;
S4, placing a first polarizer 60 on an upper end of the CF substrate 20 and contacting the first polarizer 60 with the thermoplastic film;
S5, vacuum pressing the first polarizer 60 so that the first polarizer 60 is attached to an outer surface of the CF substrate 20 while the thermoplastic film is heated and melted to fill a cavity between the first polarizer 60 and the binding end 10-1; and
S6, curing the filled thermoplastic film by UV light.

Wherein the production of LCD panel need to go through the “the front of the Array process, the middle of the Cell process, the after of the Module process” three complex processes, the cutting mother board in S1 is established after the front of the Array process has been completed and the TFT substrate 10 in the middle of the Cell process has been bonded with the CF substrate 20. The CF substrate 20 is selected to be externally disposed and a mother board is formed, the formation of the mother board according to the design of the cutting size, before cutting, the position of the side of the TFT substrate 10 beyond the CF substrate 10, the number of the CF substrate 10, and the position of the binding end 10-1 are determined, and the width of the binding end 10-1 is determined. If there is a non-binding end 10-2, the number and the width of the non-binding end 10-2 need to be considered at the same time. Of course, the liquid crystal cell formed after cutting extends beyond the CF substrate 20 at least on one side of the TFT substrate 10 to form the binding end 10-1.

Specifically, an anisotropic conductive adhesive film is laminated on the binding end 10-1, and the COF80 is electrically connected to the conductive terminal of the binding end 10-1 through the anisotropic conductive adhesive film.

Specifically, the S3 affixes the thermoplastic film to the binding end 10-1; it will be appreciated that the attachment of the COF80 has been completed prior to affixing the thermoplastic film and that the connection takes up a wide area so that when attaching the thermoplastic film, since the thermoplastic film has a certain width, the thermoplastic film is directly attached to the upper surface of the COF80, it is also possible to attach a thermoplastic film to the binding terminal 10-1 where the COF80 is not connected.

Wherein the production process is based on the structural needs, when the structure of the liquid crystal panel is such that all four side surfaces extend beyond the CF substrate, the step S3 further includes attaching a thermoplastic film on the non-binding end 10-2, when the binding end 10-1 and the non-binding end 10-2 need to be attached in a ring shape, the thermoplastic film can be directly disposed in a ring shape, the thermoplastic film directly lamination sequentially set in a ring position, in order to attach, so that the process is simple, it can be understood that, when attached on the non-binding end 10-2, the COF80 is attached directly on the upper surface of the non-binding end 10-2 because the COF80 is not connected thereto.

Correspondingly, when the groove 102 for fastening the connection is provided on the binding end 10-1 and the non-binding end 10-2, the structure of the step S3 is improved, according to the width of the groove 102 and the shape and size of the thermoplastic film, whether the thermoplastic film is directly attached to the groove 102 or directly attached to the upper surface of the groove 102 or both may be selected, the purpose is to provide a cured encapsulant in the last groove 102 to fasten the first polarizer 60 on the upper end and the TFT substrate 10 on the lower end.

Wherein, in order to prevent the thermoplastic film from flowing out of the cavity in the side portion after being melted, the thermoplastic film may be attached near the middle position during the attachment process of the thermoplastic film.

Specifically, after the attachment of all the thermoplastic films is completed, it is necessary to attach the first polarizer, prior to the S4 process, a second polarizer 50 may be attached on the outer surface of the TFT substrate 10, the second polarizer 50 is completely attached to the outer surface of the TFT substrate 10.

Specifically, in S4, the first polarizer 60 is placed on the upper end of the CF substrate 20, and the first polarizer 60 is brought into contact with the thermoplastic film. In this step, since the thermoplastic film is generally attached near the middle, and the position close to the edge is generally not attached, the cavity in the thermoplastic film needs to be completely filled after being melted, it is necessary to provide the surface of the thermoplastic film protruding from the upper surface of the CF substrate 20 at the time of attachment, at this time, the first polarizer 60 at the upper end of the CF substrate 20 is in contact with the top surface of the attached thermoplastic film.

Specifically, in S5, the first polarizer 60 is vacuum pressed, and the thermoplastic film in contact with the first polarizer 60 is heated and melted, the first polarizer 60 is moved downward and attached to the outer surface of the CF substrate 20, the thermally melted thermoplastic film fills the cavity between the first polarizer 60 and the TFT substrate 10; thereby sealing the liquid crystal panel, and also shielding the metal wire on the binding end 10-1. Wherein, the position of the vacuum pressing is a position on the first polarizer 60 opposite to the thermoplastic film, that is, only the position where the thermoplastic film attached is heated.

Wherein the UV (ultraviolet) light irradiation in S6 may irradiate the molten thermoplastic film from the side of the liquid crystal panel.

Wherein, the above-mentioned thermoplastic film is a UV-bonded and cured product, and the film is absorbed by the smooth surface before UV irradiation and is easy to dismantle. After curing the film is extremely stable, good adhesion, low shrinkage, heat and moisture preheat plasticizing characteristics, the plasticization temperature of about 60° C. The plastic film is easy to be plasticized and has good filling performance. The thermoplastic film is attached to the cavity between the TFT substrate 10 and the first polarizer 10, after vacuum pressing, it can fully fill the cavity, at the same time due to squeeze the excess plastic melt plastic spill over the first polarizer 10 and the TFT substrate 10, so that it overflows the middle of the shape of a full arc, after UV light irradiation, the shape fixed, adhesive curing; so as to make it as the appearance of the quality.

The liquid crystal panel provided by the present embodiment uses the polarizer on the CF substrate as the viewing surface and the binding end of the liquid crystal panel between the polarizer and the TFT substrate, the encapsulant formed by melting the thermoplastic film fills the gap between the polarizer and the TFT substrate without the need to set a binding frame to obscure the bind end, thus realizing the bezel less design and enhancing the visual effect and viewing experience of the whole machine. At the same time, the grooves in the liquid crystal panel are designed so that the width of the non-display area is reduced in the liquid crystal panel with the same width, but the tightening of the polarizer with the TFT substrate is rather reversed. In the manufacturing method of the liquid crystal panel provided by the present embodiment, by attaching a thermoplastic film on the binding end and the non-binding end and pressing the polarizer, the shadowing of the binding end can be realized in one step and the side is encapsulated to simplify the process. And because of the process, just attached plastic mold, attached to the process of precision is not high, and without dispensing, greatly reducing production costs.

The foregoing descriptions are merely specific implementation manners of the present application. It should be noted that, for those skilled in the art, several improvements and modifications can be made without departing from the principle of the present disclosure, and these improvements and modifications should also be considered as the protection scope of the present application.

What is claimed is:

1. A liquid crystal panel, comprising a TFT substrate, a CF substrate disposed on the TFT substrate, liquid crystal filled between the TFT substrate and the CF substrate, and a first polarizer attached to an outer surface of the CF substrate, wherein at least one end surface of the TFT substrate is beyond the side end surface of the CF substrate to form a non-displayed binding end for connecting a COF, the first polarizer completely covers the TFT substrate, an encapsulant is disposed between the first polarizer and the binding end.

2. The liquid crystal panel according to claim 1, wherein the encapsulant is formed by melting a thermoplastic film.

3. The liquid crystal panel according to claim 2, wherein the binding end is laminated with an anisotropic conductive adhesive film, and the COF is electrically connected with a conductive terminal of the binding end through the anisotropic conductive adhesive film.

4. The liquid crystal panel according to claim 1, wherein remaining ends of the TFT substrate are beyond an end surface on a corresponding side of the CF substrate to form a non-displayed non-binding end, the non-binding end is connected to the binding end and surrounds a surrounding of the CF substrate, the encapsulant is disposed between the first polarizer and the non-binding end.

5. The liquid crystal panel according to claim 4, wherein the binding end and/or the non-binding end is provided with a concave groove downwardly, and the encapsulant is arranged in the concave groove and extends out of an upper end surface of the concave groove.

6. The liquid crystal panel according to claim 5, wherein the encapsulant is formed by melting a thermoplastic film.

7. The liquid crystal panel according to claim 6, wherein the binding end is laminated with an anisotropic conductive adhesive film, and the COF is electrically connected with a conductive terminal of the binding end through the anisotropic conductive adhesive film.

8. A method for manufacturing a liquid crystal panel, comprising:
cutting a mother board to form a liquid crystal cell with an externally disposed CF substrate; wherein the TFT substrate of the liquid crystal cell comprises a binding end;
electrically connecting a COF with the binding end;
attaching a thermoplastic film to the binding end;
placing a first polarizer on an upper end of the CF substrate and contacting the first polarizer with the thermoplastic film;
vacuum pressing the first polarizer so that the first polarizer is attached to an outer surface of the CF substrate while the thermoplastic film is heated and melted to fill a cavity between the first polarizer and the binding end; and
curing the filled thermoplastic film by UV light.

9. The method for manufacturing a liquid crystal panel according to claim 8, wherein a surface of thermoplastic film protrudes from an upper surface of the CF substrate before vacuum pressing.

10. The method for manufacturing a liquid crystal panel according to claim 9, wherein a position of the vacuum pressing is on the first polarizer opposite to the thermoplastic film.

11. The method for manufacturing a liquid crystal panel according to claim 8, wherein the TFT substrate of the liquid crystal cell further comprises a non-binding end; in attaching the thermoplastic film, the thermoplastic film must be attached to a surface of the non-binding end at the same time; the thermoplastic film is heated and melted to fill the cavity between the first polarizer and the non-binding end.

12. The method for manufacturing a liquid crystal panel according to claim 11, wherein a surface of thermoplastic film protrudes from an upper surface of the CF substrate before vacuum pressing.

13. The method for manufacturing a liquid crystal panel according to claim 12, wherein a position of the vacuum pressing is on the first polarizer opposite to the thermoplastic film.

14. A display device, comprising a backlight module and a liquid crystal panel, wherein the liquid crystal panel comprises a TFT substrate, a CF substrate disposed on the TFT substrate, liquid crystal filled between the TFT substrate and the CF substrate, and a first polarizer attached to an outer surface of the CF substrate, wherein at least one end surface of the TFT substrate is beyond the side end surface of the CF substrate to form a non-displayed binding end for connecting a COF, the first polarizer completely covers the TFT substrate, an encapsulant is disposed between the first polarizer and the binding end, the backlight module is disposed on a side of the TFT substrate facing away from the CF substrate and light emitted from the backlight module is emitted from a surface of the CF substrate after passing through the TFT.

15. The display device according to claim 14, wherein the encapsulant is formed by melting a thermoplastic film.

16. The display device according to claim 15, wherein the binding end laminated with an anisotropic conductive adhesive film, and the COF is electrically connected with a conductive terminal of the binding end through the anisotropic conductive adhesive film.

17. The display device according to claim 14, wherein remaining ends of the TFT substrate are beyond an end surface on a corresponding side of the CF substrate to form a non-displayed non-binding end, the non-binding end is connected to the binding end and surrounds a surrounding of the CF substrate, the encapsulant is disposed between the first polarizer and the non-binding end.

18. The display device according to claim 17, wherein the binding end and/or the non-binding end is provided with a concave groove downwardly, and the encapsulant is arranged in the concave groove and extends out of an upper end surface of the concave groove.

19. The display device according to claim 18, wherein the encapsulant is formed by melting a thermoplastic film.

20. The display device according to claim 19, wherein the binding end is laminated with an anisotropic conductive adhesive film, and the COF is electrically connected with a conductive terminal of the binding end through the anisotropic conductive adhesive film.
